(19) United States
(12) Patent Application Publication
(10) Pub. No.: US 2006/0003587 A1
(43) Pub. Date: Jan. 5, 2006

(54) Grinding method for a sapphire wafer

(76) Inventor: Chih-Ming Hsu, Taoyuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/168,513

(22) Filed: Jun. 29, 2005

(30) Foreign Application Priority Data
Jul. 2, 2004 (TW) 093119978

(51) Int. Cl. H01L 21/302

(52) U.S. Cl. 438/691

(57) ABSTRACT

The present invention discloses a grinding method for a sapphire wafer, wherein a sapphire wafer is firstly provided, and the sapphire wafer has a substrate and an electrically-conductive layer; the sapphire wafer is fixed onto a fixing base; the fixing base is further fixed to a machining table, and the substrate of the sapphire wafer is ground thereon; then, the fixing base is placed on a polishing disc, and the substrate is further thinned thereon; and lastly, the substrate is completely removed via an etching method. The present invention can shorten the time for removing the substrate of a sapphire wafer and also shorten the time for LED fabrication process; thus, the cost is reduced. Further, LED can work normally at high temperature, and the danger resulting from LED's working at high temperature can also be lessened.

### BACKGROUND OF THE INVENTION

1. Field of the Invention

The present invention relates to a grinding method for a sapphire wafer, particularly to a grinding method for a sapphire wafer, which is applied to light emitting diodes.

2. Description of the Related Art

LED (light emitting diode) is a luminescent light-emitting element and can convert electric energy into light energy in high efficiency. LED is also a tiny solid-state light source. LED primarily comprises a p-n junction of semiconductor, and when an appropriate voltage is applied to both ends of the p-n junction, the combination of electrons and electron holes will emit photons. LED has the advantages of miniature size, low power consumption, little heat generation, long service life, and superior vibration resistance. LED has been extensively used in daily living, such as illumination devices, backlight sources, advertisement signs, traffic signals, electric torches, camera flashlights, and decoration lights.

In the application of large-size LED, such as a big signboard, LED also needs to have high brightness. However, high brightness is equal to high energy, and the temperature of LED will rise to high. If the heat resistance LED is insufficient, large-size LED may incur a danger.

Therefore, a technology utilizing a sapphire wafer to fabricate LED has been developed. As a sapphire wafer has the advantages of high hardness, high transparency, high melting point, and high heat resistance, the LED fabricated with a sapphire wafer can work normally at high temperature. When a sapphire wafer is used to fabricate LED, the sapphire will have an insulation layer. Currently, the insulation layer is removed via a laser method. However, the laser method makes the cost rise. Besides, the removing speed is very low, which increases the fabrication time of LED.

Accordingly, the present invention proposes a grinding method for a sapphire wafer to overcome the abovementioned problems.

### SUMMARY OF THE INVENTION

The primary objective of the present invention is to provide a grinding method for a sapphire wafer, wherein the substrate of a sapphire wafer is completely removed not via a laser method but via an etching method, and the fabrication cost thereof is lowered.

Another objective of the present invention is to provide a grinding method for a sapphire wafer, wherein the substrate of a sapphire wafer is removed via a machining table, polishing liquid, and an etching method, and the time for removing the substrate is shortened, and LED fabrication is also accelerated.

Yet another objective of the present invention is to provide a grinding method for a sapphire wafer, wherein a heat-resistant sapphire wafer is used in LED fabrication, which reduces the danger incurred by LED's working at high temperature and enables LED to work normally at high temperature.

To achieve the aforementioned objectives, the present invention proposes a grinding method for a sapphire wafer, wherein a sapphire wafer is firstly provided, and the sapphire wafer has a substrate and an electrically-conductive layer; the sapphire wafer is fixed to a fixing base; the fixing base is further fixed to a machining table, and the substrate of the sapphire wafer is ground thereon; then, the substrate is further thinned; lastly, the substrate is completely removed via an etching method, and the electrically-conductive layer is exposed.

To enable the objectives, technical contents, characteristics, and accomplishments of the present invention to be more easily understood, the embodiments of the present invention are to be described below in detail in cooperation with the attached drawings.

### BRIEF DESCRIPTION OF THE DRAWINGS

FIG. 1(a) to FIG. 1(d) show schematically the steps of the grinding method for a sapphire wafer according to the present invention.

FIG. 2 is a section view showing that a metallic layer is joined to the bottom of the sapphire wafer according to the method of the present invention.

FIG. 3 is a section view of LED fabricated according to the method of the present invention.

### DETAILED DESCRIPTION OF THE INVENTION

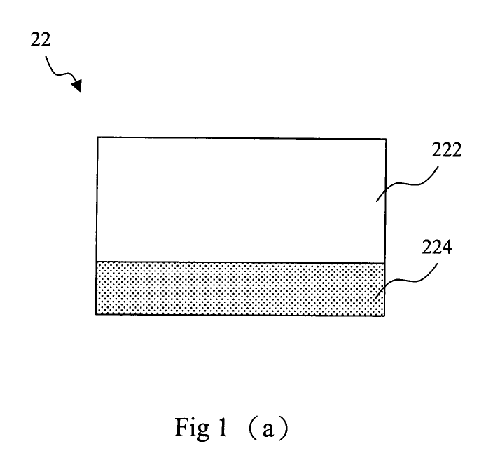

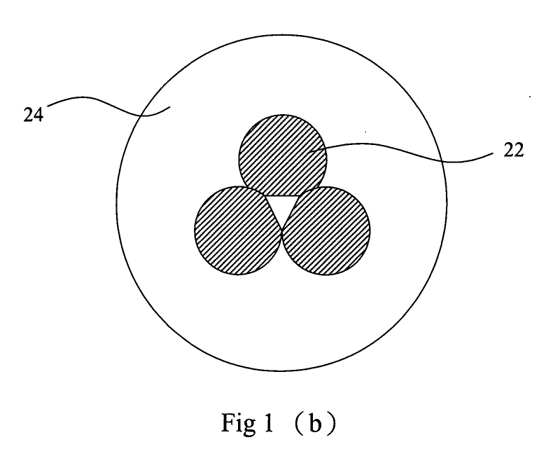

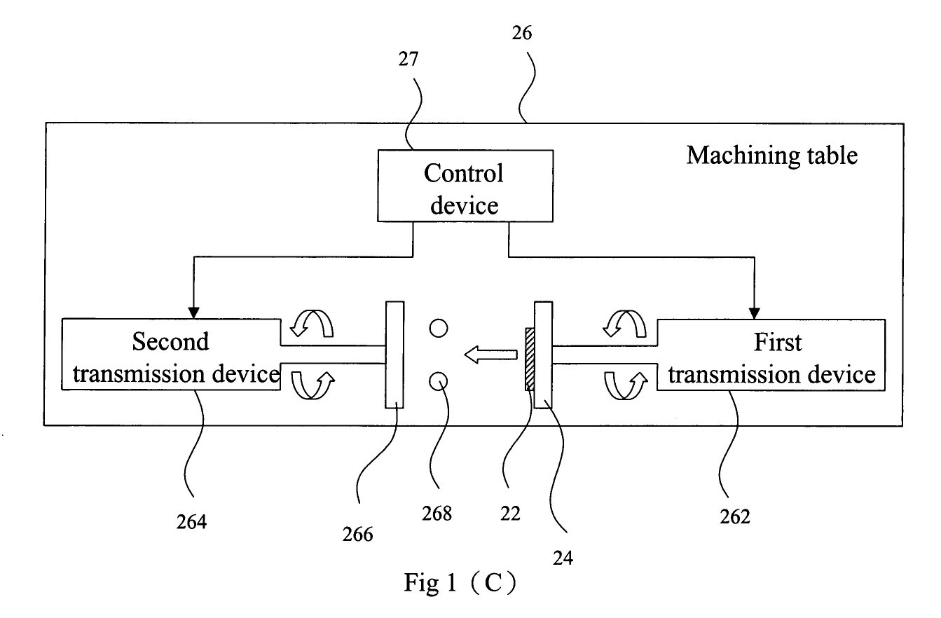

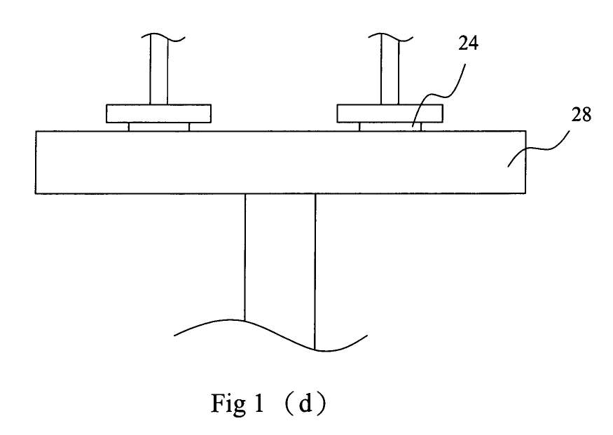

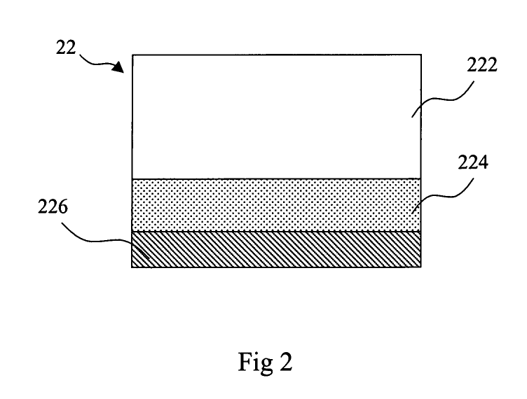

Refer to from FIG. 1(a) to FIG. 1(d) showing the steps of the grinding method for a sapphire wafer according to the present invention. In the present invention, three sapphire wafers 22 are firstly provided. As shown in FIG. 1(a), each sapphire wafer 22 comprises a substrate 222 and an electrically-conductive layer 224, wherein the substrate 222 is an insulation layer. Next, as shown in FIG. 1(b), those three sapphire wafers 22 are stuck to a fixing base 24 with a wax, and a pressure ranging from 1 to 10 kg/cm² is applied to fix those sapphire wafers 22 onto the fixing base 24, wherein the fixing base 24 may be made of a ceramic material. Next, as shown in FIG. 1(c), the fixing base 24 is further fixed onto a machining table 26 via a vacuum-suction method, and the substrate 222 of the sapphire wafers 22 are roughly ground to a thickness of from 50 to 200 μm. Next, as shown in FIG. 1(d), a fine grinding follows, and the fixing base 24 is disposed on a polishing disc 28, and a polishing solution is used to thin the substrate 222 of the sapphire wafers 22 to a thickness less than 10 μm. Lastly, the substrate 222 is completely removed via an etching method, wherein the etching method may be either a dry etching or a wet etching, and the electrically-conductive layer 224 is thus exposed.

Refer to FIG. 1(c). The machining table 26 has a first transmission device 262 and a second transmission device 264, wherein the first and the second transmission devices 262, 264 may both be motors. The second transmission device 264 has a grinding wheel 266, and the grinding wheel 266 may comprises diamonds. The fixing base 24 is fixed onto the first transmission device 262 via a vacuum-suction method, and the grinding wheel 266 is disposed corresponding to the sapphire wafers 22 on the fixing base 24. The first transmission device 262 can drive the fixing base 24 to move back and forth for some distance according to grinding parameters stored in a control device 27, and the grinding parameters includes thickness ground off, grinding time, and a grinding mode. The control device 27 controls the second transmission device 264 to rotate and move left or right. Thereby, the sapphire wafers 22 and the grinding wheel 266 can move to each other, and the substrates 222 of the sapphire wafers 22 can be roughly ground. Further, two coolant nozzles 268 are installed in the machining table 26 to spray a liquid coolant in order to cool the sapphire wafers 22 and the grinding wheel 266 lest the temperature rise too much in the rough grinding.

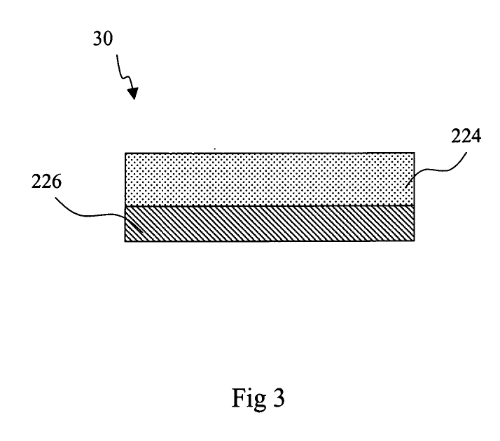

The sapphire wafer of the present invention can be applied to a large-size LED. When the sapphire wafer is applied to LED, a metallic layer 226 or another wafer is firstly joined onto the bottom of the electrically-conductive layer 224 of the sapphire wafer 22, and the metallic layer is made of a metal, which can replace the substrate 222 of the sapphire wafer 22, such as copper, gold, molybdenum, or aluminum. The substrate 222 of the sapphire wafer 22 is an insulator, which is to be replaced by the metallic layer 226 or another wafer. The electrically-conductive layer 224 and the metallic layer 226/another wafer have electrodes of opposite polarities. Next, as shown in FIG. 1(b), the sapphire wafer 22 is fixed to the fixing base 24, and the following is the same as the grinding steps mentioned above, and it is no more described repeatedly herein. As shown in FIG. 3, after the substrate 222—the insulation layer—of the sapphire wafer 22 has been completely removed, only the electrically-conductive layer 224 and the metallic layer 226/another wafer remain. When the electrically-conductive layer 224 and the metallic layer 226/another wafer having opposite-polarity electrodes are enabled to be conductive to form a conductor 30, it becomes an LED and can illuminate.

The present invention proposes a grinding method for a sapphire wafer, which can be used to fabricate large-size LED's, and wherein the substrate of a sapphire wafer is completely removed not via a laser method but via an etching method, and the fabrication cost thereof is lowered, and wherein the substrate of a sapphire wafer is removed via a machining table, polishing liquid, and an etching method, and the time for removing the substrate is shortened, and LED fabrication is also accelerated, and wherein a heat-resistant sapphire wafer is used for fabricating LED, which reduces the danger incurred by LED's working at high temperature and enables LED to work normally at high temperature.

Those embodiments described above are to clarify the present invention to enable the persons skilled in the art to understand, make, and use the present invention but not intended to limit the scope of the present invention. Any equivalent modification and variation according to the spirit of the present invention is to be included within the scope of the present invention.

What is claimed is:

1. A grinding method for a sapphire wafer, comprising the following steps:
providing at least one sapphire wafer, which further comprises a substrate and an electrically-conductive layer;
fixing said sapphire wafer onto a fixing base;
fixing said fixing base to a machining table;
grinding said substrate of said sapphire wafer;
further thinning said substrate; and
completely removing said substrate via an etching method.

2. The grinding method for a sapphire wafer according to claim 1, wherein said fixing base is made of a ceramic material.

3. The grinding method for a sapphire wafer according to claim 1, which further comprises a step of joining at least one metallic layer onto the bottom of said electrically-conductive layer of said sapphire wafer before the step of said “fixing said sapphire wafer onto a fixing base”.

4. The grinding method for a sapphire wafer according to claim 1, which further comprises a step of joining at least one wafer onto the bottom of said electrically-conductive layer of said sapphire wafer before the step of said “fixing said sapphire wafer onto a fixing base”.

5. The grinding method for a sapphire wafer according to claim 1, wherein said wafer is stuck to said fixing base with a wax and fixed onto said fixing base via applying a pressure.

6. The grinding method for a sapphire wafer according to claim 5, wherein said pressure ranges from 1 to 10 kg/cm².

7. The grinding method for a sapphire wafer according to claim 1, wherein said machining table further comprises a first transmission device installed in said machining table, and said fixing base is fixed to said first transmission device via a vacuum-suction method, and said first transmission device drives said fixing base to move back and forth.

8. The grinding method for a sapphire wafer according to claim 7, wherein said first transmission device is a motor.

9. The grinding method for a sapphire wafer according to claim 1, wherein said machining table further comprises a second transmission device installed in said machining table, and a grinding wheel is installed to said second transmission device, and said grinding wheel is disposed corresponding to said sapphire wafer on said fixing base, and said second transmission device drives said grinding wheel to rotate and move left or right.

10. The grinding method for a sapphire wafer according to claim 9, wherein said second transmission device is a motor.

11. The grinding method for a sapphire wafer according to claim 9, wherein at least one coolant nozzle is further installed to said machining table to spray a liquid coolant in order to flush and cool said sapphire wafer and said grinding wheel.

12. The grinding method for a sapphire wafer according to claim 9, wherein said grinding wheel comprises diamonds.

13. The grinding method for a sapphire wafer according to claim 7, wherein said machining table further comprises a control device and a second transmission device, and said second transmission device is installed in said machining table and disposed corresponding to said first transmission device, and said control device is used to control said first transmission device and said second transmission device.

14. The grinding method for a sapphire wafer according to claim 9, wherein said machining table further comprises a control device and a first transmission device, and said first transmission device is installed in said machining table and disposed corresponding to said second transmission device, and said control device is used to control said first transmission device and said second transmission device.

15. The grinding method for a sapphire wafer according to claim 1, wherein said substrate is ground to a thickness ranging from 50 to 200 μm.

16. The grinding method for a sapphire wafer according to claim 1, wherein said “thinning said substrate” is to place said fixing base on a polishing disc and use a polishing solution to thin said substrate of said sapphire wafer.

17. The grinding method for a sapphire wafer according to claim 1, wherein said substrate is thinned to a thickness less than 10 μm.

18. The grinding method for a sapphire wafer according to claim 1, wherein said etching method may be either a dry etching or a wet etching.
